(19) United States
(12) Patent Application Publication
(10) Pub. No.: US 2021/0035854 A1
(43) Pub. Date: Feb. 4, 2021

(54) METHOD OF FORMING A STRUCTURE USING FLUORINE REMOVAL

(71) Applicant: ASM IP Holding B.V., Almere (NL)

(72) Inventors: TaeHee Yoo, Bucheon-si (KR); YoungHoon Kim, Cheonan-si (KR); SeWoong Jung, Hwaseong-si (KR)

(21) Appl. No.: 16/932,707

(22) Filed: Jul. 18, 2020

Related U.S. Application Data
(60) Provisional application No. 62/879,736, filed on Jul. 29, 2019.

(51) Int. Cl. H01L 21/762; H01L 21/311; H01L 21/02

(52) U.S. Cl. CPC H01L 21/76224; H01L 21/31116; H01L 21/02164; H01L 21/02274; H01L 21/0228

(57) ABSTRACT

Methods of forming structures that include a step of treating a layer to remove residual etchant compounds, such as fluorine, are disclosed. Exemplary methods can be used to fill features on a surface of a substrate during a device manufacturing process.

### CROSS-REFERENCE TO RELATED APPLICATIONS

This application claims the benefit of U.S. Provisional Application No. 62/879,736, filed on Jul. 29, 2019, in the United States Patent and Trademark Office, the disclosure of which is incorporated herein in its entirety by reference.

### FIELD OF INVENTION

The present disclosure generally relates to methods of forming structures suitable for use in the manufacture of electronic devices. More particularly, examples of the disclosure relate to methods that include removal of fluorine from films and to structures formed using the methods.

### BACKGROUND OF THE DISCLOSURE

Conformal film deposition may be desirable for a variety of reasons. For example, during the manufacture of devices, such as semiconductor devices, it is often desirable to conformally deposit material over features (e.g., trenches or gaps) formed on the surface of a substrate. Such techniques can be used for shallow trench isolation, inter-metal dielectric layers, passivation layers, and the like. However, with miniaturization of devices, it becomes increasingly difficult to conformally deposit material, particularly over high aspect ratio features, such as features having an aspect ratio of three or more.

Atomic layer deposition (ALD) can be used to conformally deposit material onto a surface of a substrate. For some applications, such as when precursors and/or reactants otherwise require a relatively high temperature for ALD deposition and/or when it is desired to keep a processing temperature relatively low, it may be desirable to use plasma-enhanced ALD (PEALD).

However, even with PEALD, material that is deposited can accumulate at, for example, a top area or region 104 of a gap 102, as illustrated in FIG. 1(a). As material continues to be deposited in gap 102, a void or seam can form as a result of the accumulation of material in region 104. A deposition-etch-deposition (DED) process can be used to address this problem.

In a DED process, a film or layer of material is deposited on the top and side surface of a gap (e.g., gap 102). During the deposition step, excess material accumulates in region 104, resulting in an overhung film profile near the top surface of the side wall (region 104). An etch step is used to remove the overhung portion of the film formed on the surface near the top of the gap, as illustrated in FIG. 1(b). Then, another deposition step can be carried out, following the etch step, so as to deposit additional material on the previously-deposited material, as illustrated in FIG. 1(c). The DED process can be repeated until the gap is filled and can mitigate seam and/or void formation of deposited material within a gap.

Activated NF₃ gas is often used to etch the film to remove an overhung portion of a film to facilitate seamless and/or void-free filling of gaps. Unfortunately, it has been found that when fluorine-containing gas is used as an etchant, residual fluorine remains in the deposited material. FIG. 2 illustrates X-ray photoelectron spectroscopy (XPS) analysis results of a silicon oxide material deposited within a gap, where a represents data corresponding to a silicon substrate on which the gap is formed, b represents data corresponding to a first SiO₂ layer and c represents data corresponding to a second SiO₂ layer. As illustrated, about 0.5 atomic % fluorine remains at the boundary region between SiO₂ layers.

The residual fluorine can result in corrosion of device components and/or otherwise deteriorate the device performance. Accordingly, it may be desirable to remove fluorine from the deposited material.

Existing techniques to remove residual fluorine include annealing the deposited material at temperatures higher than 900° C. However, such temperatures may be beyond a thermal budget for structures and/or result in damage to the structure—e.g., shrinkage or collapse or crack of the components of the structure. Use of high temperatures can be particularly problematic with highly integrated device structures with relatively narrow line widths.

Accordingly, improved methods for forming structures, particularly for methods of filling gaps during the formation of a structure, are desired.

Any discussion, including discussion of problems and solutions, set forth in this section has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

Various embodiments of the present disclosure relate to methods of forming structures suitable for use in the formation of devices. While the ways in which various embodiments of the present disclosure address drawbacks of prior methods and structures are discussed in more detail below, in general, exemplary embodiments of the disclosure provide improved methods that include removal of residual fluorine from material.

In accordance with at least one embodiment of the disclosure, a method of forming a structure includes providing a substrate having a feature, depositing a layer of material overlying the feature, etching a portion of the layer using a fluorine-containing gas; and treating a remaining portion of the layer to remove fluorine from the remaining portion. The step of depositing a layer of material can include a cyclic deposition process, such as PEALD. The step of treating can include providing one or more gases selected from the group consisting of a nitrogen-containing gas (e.g., one or more of N₂, NH₃, NO₂, N₂O, NO, N₂O₃, NO₂, N₂O₄, N₂O₅, N₄O, and N(NO₂)₃, an oxygen-containing gas (e.g., one or more of oxygen, ozone, and oxygen radicals), and argon. The fluorine-containing gas can include, for example, one or more of NF₃, ClF₃, F₂, CF₄, CHF₃, C₂F₆, CF₂Cl₂ and CF₃Cl. The step of etching can include forming activated species from the fluorine-containing gas. Similarly, the step of treating a remaining portion of the layer can include forming activated species. Steps of forming active or activated species can include using remote and/or direct plasmas. The step of depositing can be repeated a number of a times prior to proceeding to the step of etching. The step of etching can include a cyclic process, which can be repeated a number of b times prior to proceeding to the step of treating. The step of treating can include a cyclic process, which can be repeated a number of c times prior to proceeding to the next step of depositing a layer of material. The steps of depositing, etching, and treating can be repeated n times. After the final etch step, a final layer of material can be deposited by repeating a deposition cycle a number of d times.

In accordance with at least one other embodiment of the disclosure, a method of filling a gap includes providing a substrate having a gap on a surface of the substrate, depositing a layer of material overlying the gap, etching a portion of the layer using a fluorine-containing gas, treating a remaining portion of the layer to remove fluorine from the remaining portion, and repeating the steps of depositing, etching, and treating until the gap is filled with the material. The step of treating can include providing one or more gases selected from the group consisting of one or more of nitrogen-containing gas, oxygen-containing gas, and argon, such as any of the nitrogen-containing gases, oxygen-containing gases or argon noted herein. The step of depositing a layer of material can include a cyclic process, such as PEALD. The steps of depositing, treating and/or etching can include use of activated species that can be formed using a remote and/or a direct plasma. Various steps and/or all steps of the method can be repeated until the gap is filled. For example, the step of depositing can include a cyclic process, which can be repeated a number of a times prior to proceeding to the step of etching; the step of etching can include a cyclic process, which can be repeated a number of b times prior to proceeding to the step of treating; and/or the step of treating can include a cyclic process, which can be repeated a number of c times prior to proceeding to the next step of depositing a layer of material. The steps of depositing, etching, and treating can be repeated n times. After the final etch step, a final layer of material can be deposited by repeating a deposition cycle a number of d times.

In accordance with yet further exemplary embodiments of the disclosure, a structure is formed, at least in part, according to a method described herein. The material can be or include, for example, insulating material, such as an oxide—e.g., silicon oxide. Because fluorine is removed from the material, the material, and particularly an interface of the material between two layers, can have a fluorine content of less than 0.25 at % or less than 0.10 at %.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method of filling a gap.

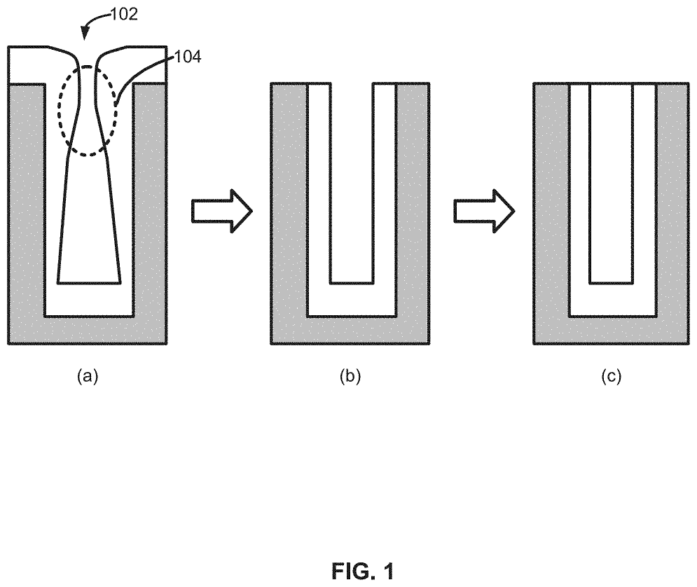

FIG. 2 illustrates XPS data, showing residual fluorine remaining in deposited material deposited.

FIG. 3 illustrates a method in accordance with at least one embodiment of the disclosure.

FIG. 4 illustrates structures formed in accordance with at least one embodiment of the disclosure.

FIG. 5 illustrates process sequence according to an example of the present disclosure.

FIG. 6 illustrates XPS analysis results for an Ar purge treatment according to an example of the present disclosure.

FIG. 7 illustrates XPS analysis results for N₂ plasma treatment according to an example of the present disclosure.

FIG. 8 illustrates XPS analysis results for O₂ plasma treatment according to an example of the present disclosure.

FIG. 9 illustrates a comparison of an amount of residual fluorine using no treatment and treatment steps in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of forming structures and to structures formed using the methods. By way of examples, the methods described herein can be used to fill features, such as gaps (e.g., trenches or vias) on a surface of a substrate with material, such as insulating (e.g., dielectric) material. By way of particular examples, the material can include silicon oxide.

In this disclosure, “gas” may include material that is a gas at room temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, which includes a seal gas, such as a rare gas. In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, other than precursors, that activates a precursor, modifies a precursor, or catalyzes a reaction of a precursor, wherein the reactant may provide an element (such as O, N, C) to a film matrix and become a part of the film matrix, when, for example, radio frequency (RF) power is applied. In some cases, the terms precursor and reactant can be used interchangeably. The term “inert gas” refers to a gas that does not take part in a chemical reaction to an appreciable extent and/or a gas that excites a precursor when RF power is applied, but unlike a reactant, it may not become a part of a film matrix to an appreciable extent.

As used herein, the term “substrate” may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various features, such as gaps, recesses, vias, lines, and the like formed within or on at least a portion of a layer or bulk material of the substrate.

In some embodiments, “film” refers to a layer extending in a direction perpendicular to a thickness direction. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not.

As used herein, the term “layer comprising silicon oxide” or “silicon oxide layer” can refer to a layer whose chemical formula can be represented as including silicon and oxygen. Layers comprising silicon oxide can include other elements, such as one or more of nitrogen, carbon, or mixture thereof.

As used herein, the term “structure” can refer to a partially or completely fabricated device structure. By way of examples, a structure can include a substrate with one or more features formed thereon.

As used herein, the term “cyclic deposition process” can refer to a vapor deposition process in which deposition cycles, typically a plurality of consecutive deposition cycles, are conducted in a process chamber. Cyclic deposition processes can include cyclic chemical vapor deposition (CVD) and atomic layer deposition processes.

As used herein, the term “atomic layer deposition” (ALD) can refer to a vapor deposition process in which deposition cycles, typically a plurality of consecutive deposition cycles, are conducted in a process chamber. Typically, during each cycle, the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas. Plasma-enhanced ALD (PEALD) can refer to an ALD process, in which a plasma is applied during one or more of the ALD steps.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In this disclosure, “continuously” can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments.

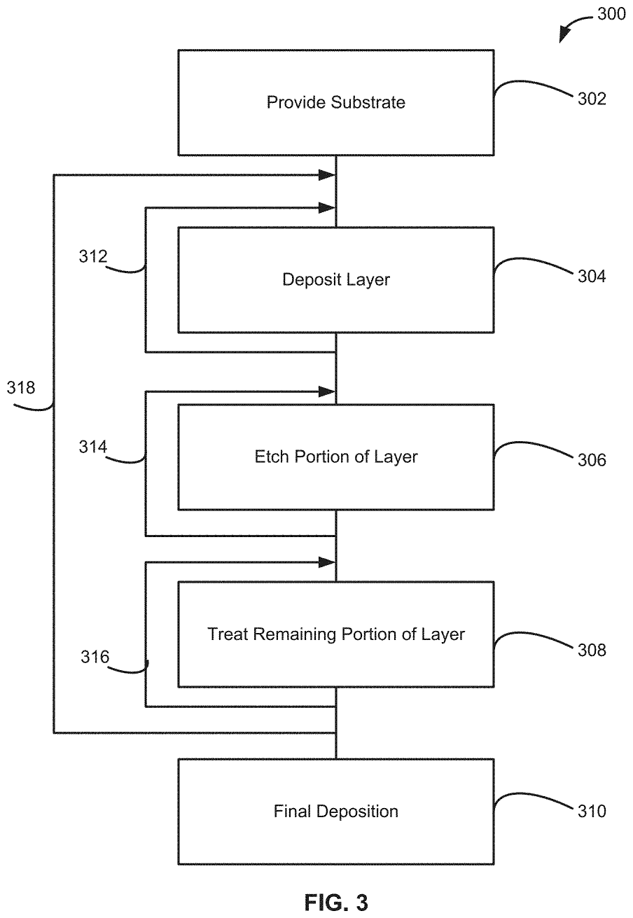

Turning again to the figures, FIG. 3 illustrates a method 300 in accordance with exemplary embodiments of the disclosure. Method 300 includes the steps of providing a substrate (step 302), depositing a layer of material (step 304), etching a portion of the layer (step 306), and treating a remaining portion of the layer (step 308). In some embodiments, method 300 can be used to fill a gap—e.g., within a feature or between features—on the surface of the substrate.

During step 302, a substrate is provided. The substrate can include features, such as trenches, vias, protrusions, or the like. The substrate can further include a layer (e.g., SiO2 or SiN) overlying the features. One or more features can have a width of about 10 nm to about 100 nm, a depth or height of about 30 nm to about 1000 nm, and/or an aspect ratio of about 3 to 100 or about 3 to about 20. The substrate can be provided within a reaction chamber during this step. Further, during step 302, the substrate can be brought to a desired temperature and pressure for subsequent processing.

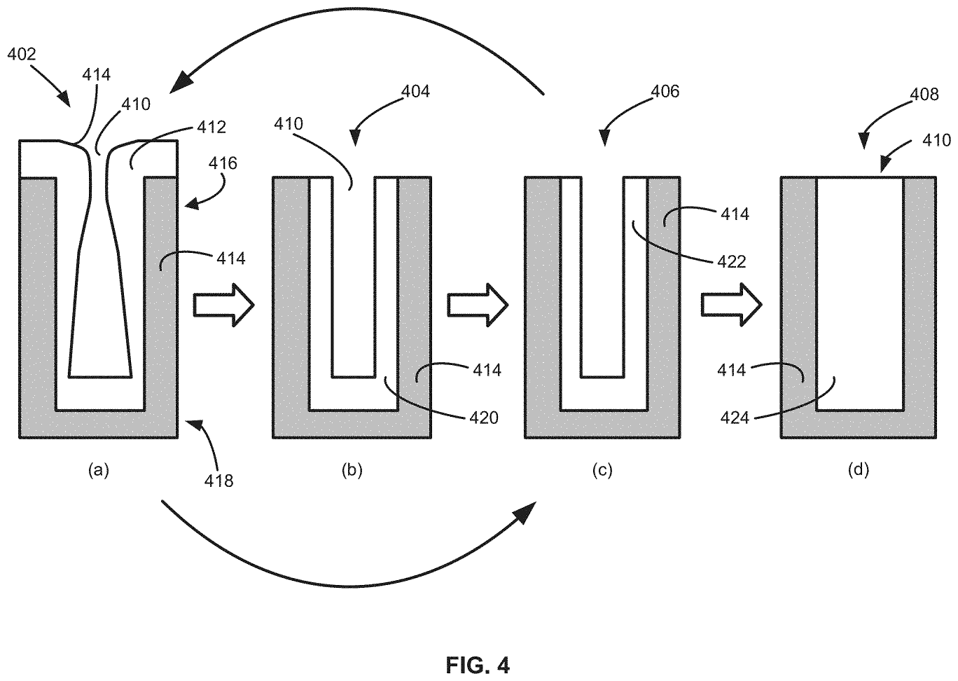

During step 304, a layer of material is deposited onto a surface of the substrate—e.g., overlying the features on the surface of the substrate. FIG. 4 illustrates a structure 402 that includes a substrate 414 having a feature (e.g., a gap) 410. During step 304, material 412 is deposited overlying feature 410/substrate 414. As illustrated, a thickness of material 412 at a top 416 of feature 410 may be relatively thick compared to a thickness of material 412 near a bottom 418 of feature 410. The relatively thick material near top 416 creates an overhang film profile, which, if not accounted for, can result in void and/or seam formation when filling feature 410.

In some embodiments, step 304 includes depositing the layer of material on the substrate/feature using a cyclic deposition process, a cyclic CVD or an ALD process. By way of particular example, the layer of material can be deposited using PEALD. The layer can include, for example, dielectric or insulating material, such as a silicon oxide layer.

An exemplary cyclic or PEALD process can include exposing the substrate to a silicon precursor, such as silane, halogensilane (diclorosilane, diiodosilane, hexachlorodisilane, octachlorotrisilane), organosilane (tris(dimethylamino)silane, bis(tert-butylamino)silane, di(sec-butylamino)silane), and heterosilane (trisilylamine, neopentasilane), purging the reaction chamber, expositing the substrate to activated reactant (e.g., oxygen) species formed by exposing a reactant gas (e.g., an oxygen source gas), such as oxygen, or O₃ (ozone), for example, to radio frequency and/or microwave radiation, purging the reaction chamber, and repeating these steps until an initial desired thickness of the layer is obtained. The step of repeating is illustrated as loop 312. In the case of cyclic CVD, a reactant and a precursor can be introduced into the reaction chamber at the same time. The reactants and/or reaction byproducts can be purged as described herein. Further, hybrid CVD/PECVD-ALD/PEALD process can be used, wherein a reactant and precursor can react in the gas phase for a period of time and wherein some ALD occurs.

During step 304, a temperature within the reaction chamber can be about 300° C. to about 550° C., about 350° C. to about 400° C., or about 450° C. to about 600° C. A pressure within the reaction chamber can be about 0.5 Torr to about 10 Torr, about 1 Torr to about 8 Torr, or about 2 Torr to about 7 Torr. A power for the, e.g., RF power for producing a plasma can be about 400 W to about 1,500 W, about 600 W to about 1,200 W, or about 800 W to about 1,000 W.

During step 306, a portion of the layer deposited during step 304 is etched. For example, a fluorine-containing gas can be used to etch a portion of material 412 to form structure 404, leaving a remaining portion of the material 420 within gap 410, as illustrated in FIG. 4.

Step 306 can be a cyclical etch process, wherein an etchant is introduced into the reaction chamber, and then the reaction chamber is purged—e.g., with the assistance of a purge gas and/or vacuum, and then introducing the etchant again and/or introducing another etchant into the reaction chamber and purging the reaction chamber; these steps can be repeated, as illustrated by loop 314 in FIG. 3.

An exemplary etchant for use during step 306 can include one or more of NF₃, ClF₃, F₂, CF₄, CHF₃, C₂F₆, CF₂Cl₂ and CF₃Cl. Activated species can be formed during step 306 by activating by plasma the etchant gas and optionally one or more inert gases, such as argon and/or nitrogen, to form a plasma. Activated species from the reactant gas can be formed using a remote and/or direct plasma.

A temperature within a reaction chamber during step 306 can be between about 300° C. and about 550° C., about 350° C. and about 500° C., or about 400° C. and about 450° C. A pressure within the reaction chamber can be about 0.5 Torr to about 10 Torr, about 1 Torr to about 8 Torr, or about 2 Torr to about 7 Torr. A power for the e.g., RF power for producing a plasma can be about 100 W to about 600 W, about 200 W to about 500 W, or about 300 W to about 400 W. The reaction chamber can be the same or different from the reaction chamber used during step 304. Thus, in some cases, steps 304 and 306 can be performed continuously.

During step 308, the remaining portion of material (e.g., remaining portion of material 420) is treated to remove residual etchant material (e.g., fluorine) from the remaining portion of material, to form structure 406, having material 422 with residual etchant material removed.

Step 308 can include providing a treatment gas to a reaction chamber, which may be the same or different from the reaction chamber used during any of steps 304, 306. Thus, steps 304-308 or steps 306 and 308 can be performed continuously.

A treatment gas is introduced to the reaction chamber during step 308. The treatment gas can include, for example, one or more gases selected from the group consisting of a nitrogen-containing gas, an oxygen-containing gas, and argon. The nitrogen-containing gas can include one or more of N₂ (nitrogen), NH₃ (ammonia), NO₂ (nitrogen dioxide), N₂O (nitrous oxide), NO (nitric oxide), N₂O₃ (dinitrogen trioxide), NO₂ (nitrogen dioxide), N₂O₄ (dinitrogen tetroxide), N₂O₅ (dinitrogen pentoxide), N₄O (nitrosylazide), and N(NO₂)₃ (trinitramide). The oxygen-containing gas can include one or more of oxygen, ozone, and oxygen radicals. Activated species can be formed during step 308 by activating the treatment gas and optionally one or more inert gases, such as argon and/or nitrogen, to form a plasma. Activated species from the treatment gas can be formed using a remote and/or direct plasma.

Step 308 can include purging the reaction chamber—e.g., with the aid of an inert gas and/or a vacuum. Further, step 308 can be repeated a number of times, as illustrated by loop 316.

Steps 304-308 can be repeated as illustrated by loop 318. For example, step 304 can be performed a times, step 306 can be performed b times, step 308 can be performed c times and loop 318 can be performed n times.

After the final step 308, method 300 can proceed to final deposition step 310 to form structure 408 having feature 410 filled with material 424. Step 310 can be the same or similar to step 304 and can be repeated a number of d times until feature 410 is filled. Optionally, a CMP step or etch step may be provided before the step (d) of FIG. 4 so as to planarize the top of the structure 402 including a material 412. A fluorine content of material 424, particularly at an interface between deposited layers (e.g., layers that are separated by an etch process), can be less than 0.25 at % or less than 0.15 at % or less than 0.10 at % or less than 0.05 at %.

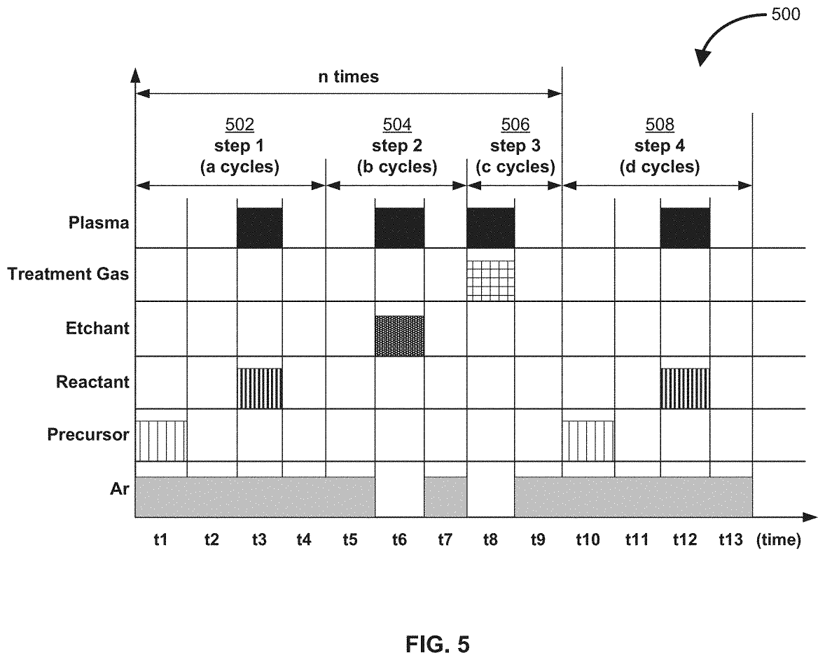

FIG. 5 illustrates a cyclic method 500 in accordance with a particular example of the disclosure. Method 500 includes the steps of depositing a layer of material (step 502), etching a portion of the layer (step 504), treating a remaining portion of the layer (step 506), and a final step of depositing material (step 508). Method 500 can also include a step of providing a substrate within a reaction chamber, which can be the same or similar to step 302, described above. Further, similar to method 300, method 500 can be used to fill a gap—e.g., within a feature or between features—on the surface of the substrate.

In the illustrated example, step 502 includes pulsing a precursor to a reaction chamber for a period t1, purging the reactant from the reaction chamber for a period t2, providing activated reactant species to a reaction chamber for a period t3, and purging the reaction chamber for a period t4. The purging can include providing a vacuum and/or a purge gas to the reaction chamber. The times for each of t1-t4 can vary; however, in accordance with examples of the disclosure, t1 can range from about 0.1 sec to about 1 sec, about 0.2 sec to about 0.8 sec, or about 0.4 sec to about 0.6 sec; t2 can range from about 0.1 sec to about 10 sec, about 2 sec to about 8 sec, or about 4 sec to about 6 sec; t3 can range from about 0.2 sec to about 10 sec, about 2 sec to about 8 sec, or about 4 sec to about 6 sec; t4 can range from about 0.1 sec to about 10 sec, about 2 sec to about 8 sec, or about 4 sec to about 6 sec. A flowrate of the precursor can range from about 1,000 sccm to about 3,000 sccm, about 1,500 sccm to about 2,500 sccm, or about 1,000 sccm to about 2,000 sccm. A flowrate of the reactant can range from about 1,000 sccm to about 3,000 sccm, about 1,500 sccm to about 2,500 sccm, or about 1,800 sccm to about 2,200 sccm. Step 502 can be repeated for a times.

Step 504 can include (optionally) purging the reaction chamber for a period t5, etching a portion of a layer for a period t6, and purging the reaction chamber for a period t7. T5 can range from about 0.2 sec to about 10 sec, about 2 sec to about 8 sec, or about 4 sec to about 6 sec; t6 can range from about 0.2 sec to about 10 sec, about 2 sec to about 8 sec, or about 4 sec to about 6 sec; t7 can range from about 0.1 sec to about 10 sec, about 2 sec to about 8 sec, or about 4 sec to about 6 sec. A flowrate of the etchant can range from about 100 sccm to about 500 sccm, about 150 sccm to about 450 sccm, or about 200 sccm to about 400 sccm. Step 504 can be repeated for b times.

Step 506 can include pulsing a treatment gas to a reaction chamber for a period t8 and purging the treatment gas from the reaction chamber for a period t9. T8 can range from about 0.2 sec to about 10 sec, about 2 sec to about 8 sec, or about 4 sec to about 6 sec and t9 can range from about 0.1 sec to about 10 sec, about 2 sec to about 8 sec, or about 4 sec to about 6 sec. A flowrate of the treatment gas can range from about 1,000 sccm to about 3,000 sccm, about 1,500 sccm to about 2,000 sccm, or about 1,800 sccm to about 2,200 sccm. Step 506 can be repeated for c times.

As illustrated, steps 502-506 can be repeated a number of n times—e.g., to form structure 406. After the final step 506, step 508 can be performed to fill a gap. Step 508 includes pulsing a precursor to a reaction chamber for a period t10, purging the reactant from the reaction chamber for a period t11, providing activated reactant species to a reaction chamber for a period t12, and purging the reaction chamber for a period t13. The times for each of t10-t13 and to flowrates of the precursor and/or reactant can be the same or similar to the corresponding values for step 502.

One or more of steps 502-508 can include a step of forming activated species. In the illustrated example, activated species are formed from reactant gas during steps 502 and 508, from etchant gas during step 504, and from treatment gas during step 506. A power used to form the activated species can be as described above in connection with method 300 and/or as set forth below.

Table 1 below illustrates exemplary ranges of variables suitable for method 500.

TABLE 1

| | | Step 1 | Step 2 | Step 3 | Step4 |
|---|---|---|---|---|---|
| Gas flow | Precursor (Si | 1000~3000 | 1000~3000 | 1000~3000 | 1000~3000 |
| (sccm) | source) | | | | |
| | (Carrier Ar) | | | | |
| | Purge Ar | 2000~10000 | 2000~10000 | 2000~10000 | 2000~10000 |
| | Reactant (O₂) | 1000~3000 | 0 | | 1000~3000 |
| | Treatment gas | | | 1000~3000 | |
| | (N₂) | | | | |
| | Etchant (NF₃) | | 100~500 | 0 | |
| Process time | Source feed | 0.1~1 | 0 | 0 | 0.1~1 |
| (sec)/cycle | Purge | 0.1~10 | 0.1~10 | 0 | 0.1~10 |
| | Plasma | 0.2~10 | 0.2~10 | 0.2~10 | 0.2~10 |
| | Purge | 0.1~10 | 0.1~10 | 0.1~10 | 0.1~10 |
| Plasma | RF Power (W) | 900 | 300 | 700~900 | 900 |
| | Freq. | 13.56 MHz | 430 KHz | 13.56 MHz | 13.56 MHz |

| | | | | |
|---|---|---|---|---|
| Process gap (mm) | 5.5~12 | 5.5~12 | 5.5~12 | 5.5~12 |
| Pressure (Torr) | 2~7 | 2~7 | 2~7 | 2~7 |
| Heater Temp (° C.) | 550 | 550 | 550 | 550 |

Process gap refers to a distance between a substrate and an electrode of a direct plasma and/or of a gas distribution device, such as a showerhead.

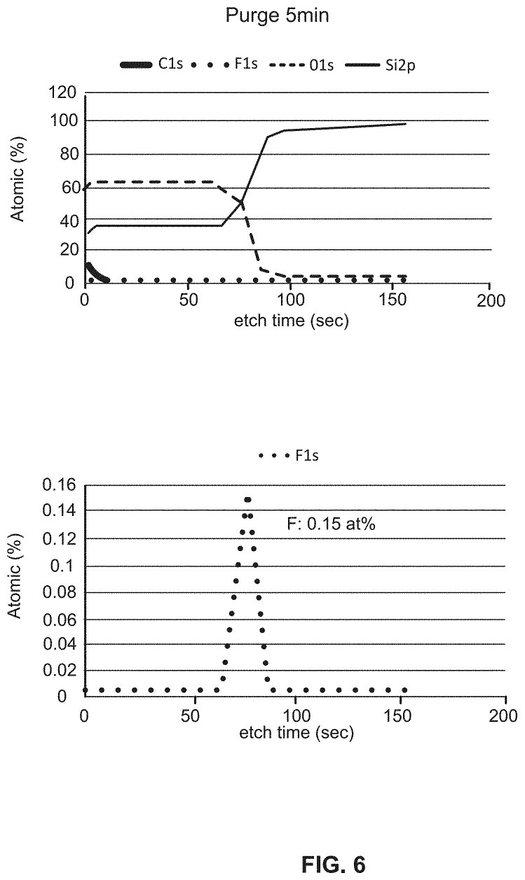

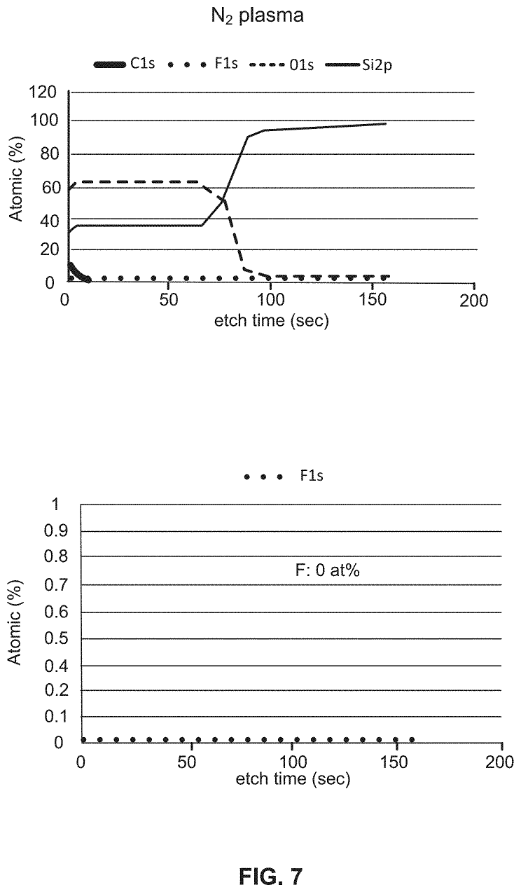

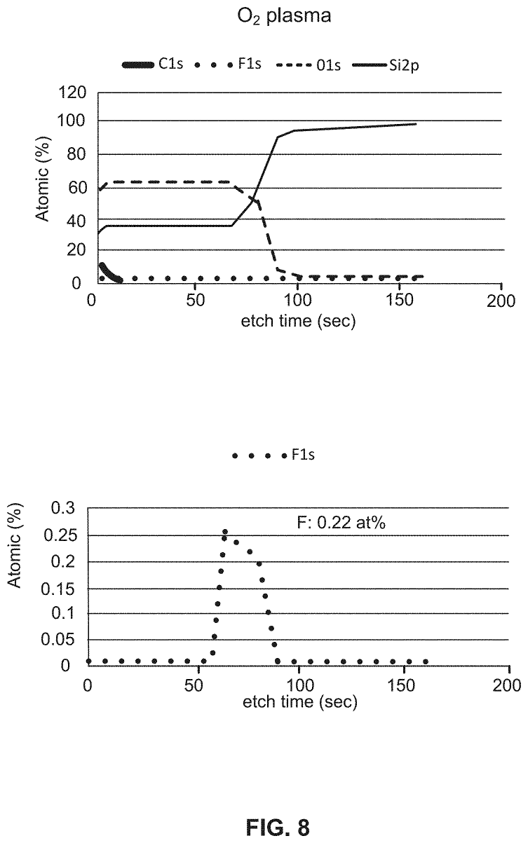

FIGS. 6-8 illustrate XPS analysis results of residual fluorine in silicon oxide films deposited using method 300 and/or method 500. FIG. 6 illustrates XPS analysis of silicon oxide films treated with argon—e.g., argon purge with no plasma (e.g., during step 308). FIG. 7 illustrates XPS analysis of silicon oxide films treated with activated nitrogen (e.g., during step 308 and/or 506). FIG. 8 illustrates XPS analysis of silicon oxide films treated with activated oxygen (e.g., during step 308 and/or 506).

With Ar purge treatment and activated oxygen treatment, Ar molecules and oxygen radicals are thought to bombard the surface of the film to thereby remove residual fluorine physically from the film; such treatment yields less residual fluorine than films with no treatment. When a nitrogen-containing gas is used and a plasma treatment is applied during steps 308, 506, no fluorine is detected in the samples.

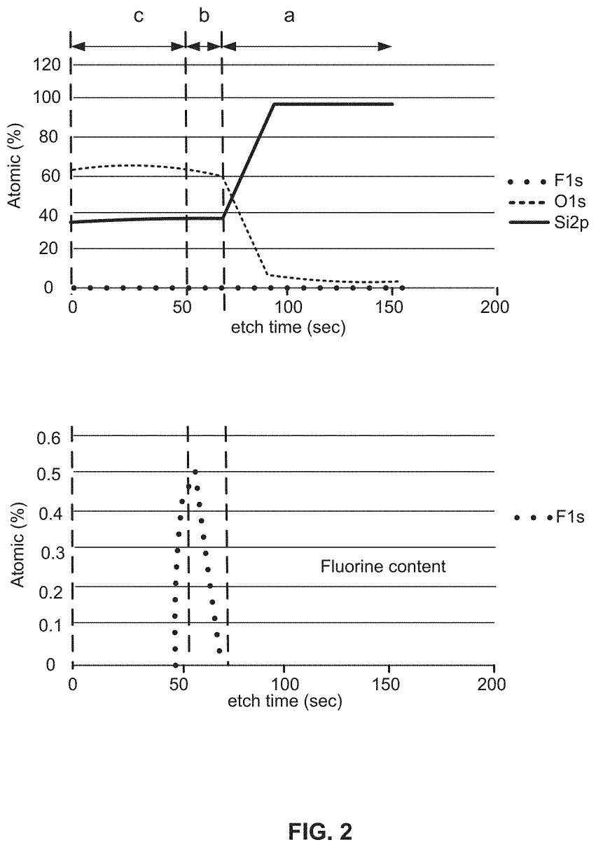

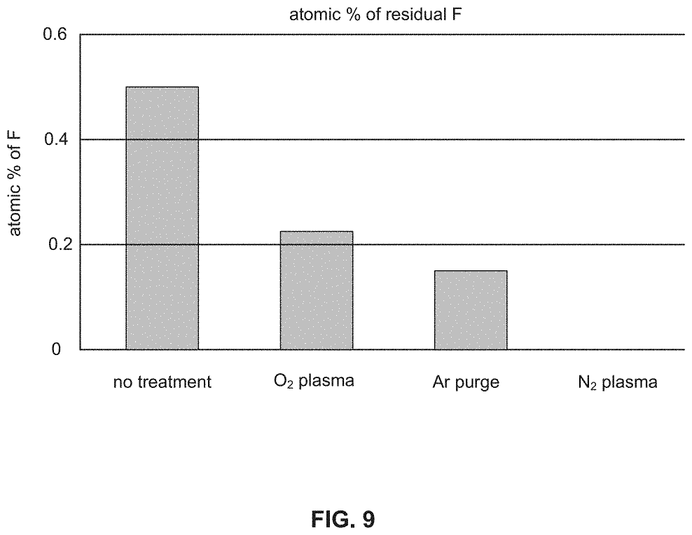

Comparing FIGS. 6-8 to FIG. 2, an amount of residual fluorine is reduced or removed physically and/or chemically by argon molecules or oxygen radicals or nitrogen radicals. FIG. 9 illustrates the amount of residual fluorine according to FIG. 2 and FIGS. 6-8. Structures formed in accordance with exemplary methods described herein may not be treated with an anneal process at high temperatures to remove fluorine from deposited material. Consequently, any damage to a device that might otherwise occur from annealing may be reduced or minimized.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a structure, the method comprising the steps of:
providing a substrate having a feature;
depositing a layer of material overlying the feature;
etching a portion of the layer using a fluorine-containing gas; and
treating a remaining portion of the layer to remove fluorine from the remaining portion.

2. The method of claim 1, wherein the step of treating comprises providing one or more gases selected from the group consisting of a nitrogen-containing gas, an oxygen-containing gas, and argon.

3. The method of claim 2, wherein the step of treating comprises providing the nitrogen-containing gas.

4. The method of claim 3, wherein the nitrogen-containing gas comprises one or more of N₂ (nitrogen), NH₃ (ammonia), NO₂ (nitrogen dioxide), N₂O (nitrous oxide), NO (nitric oxide), N₂O₃ (dinitrogen trioxide), NO₂ (nitrogen dioxide), N₂O₄ (dinitrogen tetroxide), N₂O₅ (dinitrogen pentoxide), N₄O (nitrosylazide), and N(NO₂)₃ (trinitramide).

5. The method of claim 2, wherein the step of treating comprises providing the oxygen-containing gas.

6. The method of claim 5, wherein the oxygen-containing gas comprises one or more of oxygen, ozone, and oxygen radicals.

7. The method of claim 2, wherein the step of treating comprises providing argon.

8. The method of claim 1, wherein the fluorine-containing gas is selected from one or more of NF₃, ClF₃, F₂, CF₄, CHF₃, C₂F₆, CF₂Cl₂ and CF₃Cl.

9. The method of claim 1, wherein the step of etching a portion of the layer using a fluorine-containing gas comprises forming activated species from the fluorine-containing gas.

10. The method of claim 1, wherein the step of treating a remaining portion of the layer comprises forming activated species.

11. The method of claim 10, wherein the activated species are formed using a direct plasma.

12. The method of claim 10, wherein the activated species are formed using a remote plasma.

13. The method of claim 1, wherein a temperature of a substrate during the step of treating is between about 300° C. and about 550° C., about 350° C. and about 500° C., or about 400° C. and about 450° C.

14. The method of claim 1, further comprising repeating the steps of depositing a layer of material overlying the feature, etching a portion of the layer using a fluorine-containing gas, and treating a remaining portion of the layer to remove fluorine from the remaining portion a number of n times.

15. The method of claim 14, further comprising a step of depositing a layer of material after the number of n times.

16. The method of claim 14, wherein the step of treating comprises a cyclic process, and wherein the cyclic process is repeated a number of times prior to proceeding to the step of depositing a layer of material.

17. A method of filling a gap, the method comprising the steps of:
providing a substrate having a gap on a surface of the substrate;
depositing a layer of material overlying the gap;
etching a portion of the layer using a fluorine-containing gas;
treating a remaining portion of the layer to remove fluorine from the remaining portion; and
repeating the steps of depositing, etching, and treating until the gap is filled with the material.

18. The method of claim 17, wherein the step of treating comprises providing one or more gases selected from the group consisting of one or more of nitrogen-containing gas, oxygen-containing gas, and argon.

19. The method of claim 17, wherein a temperature of a substrate during the step of treating is between about 300° C. and about 550° C., about 350° C. and about 500° C., or about 400° C. and about 450° C.

20. The method of claim 17, further comprising a step of depositing the material after a final step of treating a remaining portion of the layer.

21. The method of claim 17, wherein the step of depositing a layer of material comprises PEALD.

22. The method of claim 17, wherein the step of treating comprises forming activated species using a direct plasma.

23. The method of claim 17, wherein the step of treating comprises forming activated species using a remote plasma.

24. A structure formed according to the method of claim 1.

25. The structure according to claim 24, wherein the material comprises an insulating material.

26. The structure according to claim 25, wherein the insulating material comprises an oxide.

27. The structure according to claim 24, wherein a fluorine content in the material is less than 0.25 at %.

28. The structure according to claim 24, wherein a fluorine content in the material is less than 0.1 at %.
